(19) United States
(12) Patent Application Publication
(10) Pub. No.: US 2004/0051126 A1
(43) Pub. Date: Mar. 18, 2004

(54) Compositionally engineered CexMnyO3 and semiconductor devices based thereon

(75) Inventors: Joseph D. Cuchiaro, Colorado Springs, CO (US); Gary S. Tompa, Belle Mead, NJ (US)

Correspondence Address: William L. Botjer, PO Box 478, Center Moriches, NY, 11934, US

(73) Assignee: Structured Materials Inc.

(21) Appl. No.: 10/383,352

(22) Filed: Mar. 7, 2003

Related U.S. Application Data
(60) Provisional application No. 60/411,091, filed on Sep. 16, 2002.

(51) Int. Cl. H01L 29/76

(52) U.S. Cl. 257/295

(57) ABSTRACT

Compositionally engineered Ce_{X}Mn_{Y}O₃ (Cerium Manganate) and electronic devices based thereon When the proportion of cerium to manganese in Ce_{X}Mn_{Y}O₃ is altered, a number of the electrical properties of the material are affected, among them are the ferroelectric and dielectric constant. By adjusting the proportion of cerium to manganese the deposited material can be either dielectric or ferroelectric. A silicon based transistor having a gate of ferroelectric Ce_{X}Mn_{Y}O₃ forms a single transistor non volatile memory cell, which does not require additional layers and thus greatly reduces architecture complexity and utilizes the standard operating voltage of a DRAM. A silicon based device having a capacitor, inductor or resistor made of dielectric Ce_{X}Mn_{Y}O₃ forms a passive structure which does not require additional layers and thus greatly reduce architecture complexity.

### REFERENCE TO RELATED APPLICATIONS

This application claims priority of U.S. Provisional application No. 60/411,091 filed Sep. 16, 2002.

### BACKGROUND AND SUMMARY OF THE INVENTION

This invention relates to compositionally engineered CeₓMn_{y}O₃, methods of producing it, and electronic devices based thereon. One class of applications are nonvolatile random access memory (NVRAM) films and devices and particularly to a single transistor NVRAM device using a CeₓMn_{y}O₃ buffered ferroelectric gate that does not require additional barrier layers to operate. Another class of applications is passive films and devices and particularly capacitors, inductors and resistors using a CeₓMn_{y}O₃ dielectric to operate.

Cerium manganate (CeMnO₃) is a material with many useful and desirable properties for use in electronic devices such as capacitors, diodes and transistors. Moreover, cerium manganate can be “compositionally engineered” i.e. the proportion of cerium to maganese can be altered during the deposition process, in this application such compositionally graded material will be referred to as CeₓMn_{y}O₃. The engineered composition may be of a single value or functionally controlled throughout the layer (i.e. the proportion of Ce to Mn can be varied within a single layer). When the proportion of cerium to maganese is altered a number of the electrical properties are affected, among them are the capacitance and dielectric constant of the material. Furthermore, by varying the proportion of cerium to maganese. CeₓMn_{y}O₃ can be produced so that the material is either dielectric or ferroelectric. CeₓMn_{y}O₃ can also be alloyed with other elements such as Pr, Nd, Sm, Eu, Gd, Tb, Dy, Ho, Er, Tm, V, Ca, Sr, Y, Cu and La for the Ce position and Hf, Zr, Ti, Mg, Al, Zn, Cd, Si, Ga, Ge, Sn, Mo, Nb and Ta for Mn. Ferroelectric materials, because of their non-linear characteristics, have recently been utilized to produce nonvolatile semiconductor memory devices. Compositionally engineered ferroelectric CeₓMn_{y}O₃ produced in accordance with the present invention provides superior nonvolatile semiconductor ferroelectric memory devices because it can eliminate the need for intermediate barrier or contact layers compared to conventional ferroelectrics; since CeₓMn_{y}O₃ can be used as a dielectric or ferroelectric with or without the barrier or contact layers. Additionally, CeₓMn_{y}O₃ can be engineered to be dielectric for use in the passive devices identified above.

Integrated circuit (IC) nonvolatile memory (NVRAM) devices are being broadly developed through numerous research and industry institutions. Their primary objectives are to obtain faster read/write cycling time, lower operation voltage and improved nonvolatile lifetime and read/write endurance. The research direction is to simplify current accepted cell configurations that provide operation from two transistor/two capacitor memory cells [2T/2C] to future one transistor one capacitor [1T/1C] and to ultimately a single transistor [1T] configuration that minimizes chip area, chip layers and process steps over currently available technologies such as SRAM, EEPROM and FLASH devices. Similar advantages accrue to passive devices. The invention described herein enables these goals.

In general, current nonvolatile technologies store information electronically from electronic charge trapping across a linear dielectric layer (such as SiO₂ or SiN) to form memory devices (such as EEPROM and FLASH devices) isolating a tunnel oxide comprising the memory. These devices employ large voltages (5-12V) to drive the electronic charge through a dielectric barrier layer for information storage. The speed at which the charge migrates across the barrier for FLASH and EEPROM (milli to micro seconds) limits the device operation read/write speed. These operational limits have remained relatively constant in sequential product generations since the minimum reliable tunnel dielectric thickness (10-20 nm) has reached a physical reliability limit. Since nonvolatile memories are used with microprocessors that continually need updating and that have been continually improved to operate at lower voltages and higher frequencies, charge tunneling memories have and will limit system performance (in both multi-chip and single chip implementations). Thus, there is a need for a fast-unlimited endurance operation read/write non-electronic memory such as a physical memory mechanism to store information.

Current non-volatile IC memory devices, such as FLASH and EEPROM, require the integration of additional dielectric layers when implementing a floating gate structure that uses tunneling and hot carrier transport of electrons to charge and discharge the capacitor plates. Such additional films add to the complexity of the integration task, slow the speed of operation significantly below volatile dynamic random access memory (DRAM) or static random access memory (SRAM) capability and increase the cost of the product. The transport mechanisms require high voltage sources to achieve the required fields and reduce the dielectric quality with voltage cycling that will limit the number of endurance cycles (approximately 1.0×10E6 cycles) the device can achieve, thus significantly limiting device access iterations. Consequently, significant improvement in current nonvolatile memory technology is required to replace volatile DRAM technology as a core memory.

To overcome the speed and integration issues with tunnel memories, simplification of the memory structure through a novel approach of DRAM transistor modification is under investigation. Silicon transistor technology utilizes silicon oxide as the dielectric between the conductive transistor gate dielectric electrode and the semi-conducting silicon substrate that forms a conduction channel, along the gate length, in the silicon forms when a voltage bias is applied to the gate. Without the bias there is no possibility for conduction along the gate length providing distinct conduction states “on” and “off” in the device. Since the charge in the dielectric will dissipate with the removal of the bias, the silicon dioxide dielectric material is volatile and the device will not possess a memory of the prior state induced by the voltage bias. However, if the dielectric material could remember the previous state induced by the applied bias then the device would be nonvolatile. Therefore, ferroelectric materials have been considered as the gate dielectric to remember the previous transistor bias state since they retain a crystalline polarization that reflects image charge on capacitor electrodes after the bias is removed. This remaining physical distortion in ferroelectric crystals well defines a nonvolatile transistor device. Further, such a device could perform similarly to a DRAM. Lastly, if the ferroelectric materials can be processed and integrated the same as silicon oxide then existing tooling could be used to manufacture improved memory devices.

The integration of ferroelectric materials in a transistor gate is a difficult challenge to obtain reliable device performance. Typically, ferroelectric materials have extremely high relative dielectric constants that range from 100-1500 and when placed in the gate of a transistor require large biases to switch states. Ferroelectric materials are multiple element oxides and when placed directly in a transistor gate can form silicides, or ferroelectric containing elements that react with silicon at elevated process temperature to form low relative dielectric constant silicon oxides that producing a serial linear capacitance in the gate. These events will adversely effect the transistor and memory performance and require extrinsic solutions that limit the density and cost of this approach.

To compensate for the material interactions limiting the development of a nonvolatile ferroelectric DRAM device, non-reactive barrier oxide materials have been applied to separate the silicon form the ferroelectric. Barrier materials of Y₂O₃ and CeO₂ are non-reactive with the silicon and possess higher relative dielectric constants than silicon oxide (5-12 vs. 4) and are compatible with ferroelectric materials in a capacitor stack but still require application of large switching voltages to overcome the dielectric mismatch with the ferroelectric.

We have provided a novel material system of CeₓMn_{y}O₃ ferroelectric oxide, which, when placed in the gate of a transistor, will perform non-volatile memory function, that greatly reduces architecture complexity with a single film and that utilizes the standard voltage supply of a DRAM. We have also provided a novel material system of CeₓMn_{y}O₃ dielectric oxide, which can be used in passive components to reduce architecture complexity and electronic performance. Further, the advantages of CeₓMn_{y}O₃ are also beneficial to similar applications in non-Si based devices.

### BRIEF DESCRIPTION OF THE DRAWINGS

For a better understanding of the invention reference is made to the following drawings which are to be taken in conjunction with the detailed description to follow:

FIG. 1 is a graph of the electrical properties of a first sample of a compositionally engineered CeₓMn_{y}O₃ film constructed in accordance with the present invention;

FIG. 2 is a graph of the electrical properties of a second sample of a compositionally engineered CeₓMn_{y}O₃ film constructed in accordance with the present invention;

FIG. 3 is a sectional view of the layers (not drawn to scale) of a conventional ferroelectric transistor forming a memory cell; and

FIG. 4 is a sectional view of the layers (not drawn to scale) of a ferroelectric transistor, forming a memory cell, utilizing a ferroelectric CeₓMn_{y}O₃ combined gate and barrier layer, constructed in accordance with the present invention.

FIG. 5 is a graph of drain current versus gate voltage transfer characteristics for a sample FE FET for a positive voltage sweep (curve on left) and a negative voltage sweep (curve on right); and

FIG. 6 shows an Non-volatile Integrated Gate Bipolar Transistor (NVIGBT) utilizing a ferroelectric CeₓMn_{y}O₃ layer disposed between the gate(s) and the substrate.

### DESCRIPTION OF THE PREFERRED EMBODIMENTS

Manufacture of CeₓMn_{y}O₃

Compositionally engineered CeₓMn_{y}O₃ in accordance with this invention may be produced by a variety of processes, the dielectric/ferroelectric properties of which may be controlled by varying the composition as described herein.

### Example 1

### Sputtering

Utilizing standard sputtering equipment compositionally engineered CeₓMn_{y}O₃ can be made using sputtering from a single target of pre-mixed CeₓMn_{y}O₃ where the film composition is approximately that of the starting composition. The composition can be set to yield a dielectric or a ferroelectric. Alternatively two targets can be used—one for Ce (CeO) and one for Mn (MnO). In another alternative the targets are the elements (Ce and Mn) and a natural equilibrium oxide is allowed to form during the sputtering process. In another two target process, two sputter targets are used and the rate of sputter of one with respect to the other is changed over the course of the deposition by varying the power (and to a lesser extent other process parameters such as pressure, gas composition, target bias, target and/or substrate temperature and the like).

### Example 2

### Spin-On Metal Organic Decomposition

Compositionally engineered CeₓMn_{y}O₃ can be made using spin-on metal organic decomposition from a single precursor of pre-mixed chemicals (such as—2-ethylhexanoate in xylenes and n-butyl acetate), but not limited to 2-ethylhexanoate in xylenes and n-butyl acetate), where the film composition is approximately that of the starting composition. The composition can be set to yield a dielectric or a ferroelectric. In an alternative spin-on process the precursors are not mixed until they are brought into the reactor or a premixing chamber adjacent to the reactor—one for Ce (2-ethylhexanoate in xylenes and n-butyl acetate) and one for Mn (2-ethylhexanoate in xylenes and n-butyl acetate). In another two precursor spin on process the rate of delivery of one precursor with respect to the other is changed over the course of the deposition by varying the flow rate (and to a lesser extent other process parameters such as pressure, gas composition, substrate temperature and the like). In either the single or dual precursor process, the precursor and a diluent can be misted before deposition.

### Example 3

### Chemical Vapor Deposition

Compositionally engineered CeₓMn_{y}O₃ can be made using Chemical Vapor Deposition (CVD) from a single precursor cocktail of pre-mixed chemicals (such as—Ce (Ce(TMHD)4 Tetrakis (2,2,6,6-tetramethyl-3,5-heptanedionato) cerium) and one for Mn (Mn(TMHD)3 Tris (2,2,6,6-tetramethyl-3,5-heptanedionato) manganese), but not limited to Ce (Ce(TMHD)4 Tetrakis (2,2,6,6-tetramethyl-3,5-heptanedionato) cerium) and one for Mn (Mn(TMHD)3 Tris (2,2,6,6-tetramethyl-3,5heptanedionato) manganese) and the diluent/solvent may be any of a number of non-aqeous solvents (for this chemistry) such as tetrahydrofuran, isopropanol, octane, tetraglyme, and so on) brought into a heated zone/plenum or other geometry sufficient to significantly if not totally immediately evaporate all of the chemical mixture, where the film composition is proportional to that of the starting precursor composition, and dependent upon the processing parameters. either dielectric or ferroelectric. Alternatively, in a CVD process the precursors or precursors (with individual solvents/diluents) can remain unmixed until they are brought into the rapid/flash evaporation chamber or into separate rapid/flash evaporation zone before the deposition reactor or a premixing chamber adjacent to the reactor—one precursor for Ce (Ce(TMHD)4 Tetrakis (2,2,6,6-tetramethyl-3,5-heptanedionato) cerium) and one precursor for Mn (Mn(TMHD)3 Tris (2,2,6,6-tetramethyl-3,5heptanedionato) manganese)

Another method to make compositionally engineered CeₓMn_{y}O₃ using Chemical Vapor Deposition utilizes multiple precursors of pre-mixed chemicals (such as—Ce (Ce(TMHD)4 Tetrakis (2,2,6,6-tetramethyl-3,5-heptanedionato) cerium) and one for Mn (Mn(TMHD)3 Tris (2,2,6,6-tetramethyl-3,5heptanedionato) manganese), but not limited to Ce (Ce(TMHD)4 Tetrakis (2,2,6,6-tetramethyl-3,5-heptanedionato) cerium) and one for Mn (Mn(TMHD)3 Tris (2,2,6,6-tetramethyl-3,5heptanedionato) manganese) and the diluent/solvent may be any of tetrahydrafuran, isopropanol, and octane, tetraglyme, and the like are brought into a heated zone/plenum or other geometry sufficient to significantly if not totally immediately evaporate all of the chemical mixture, wherein the film composition which is proportional to that of the precursor composition and dependent upon the processing parameters, which is then varied one relative to another. In this process either a single vaporization zone is used or separate vaporization zones are used which may be connected to the reactor or may be separately introduced to the reactor. In the CVD processes the precursors or the precursor and the diluent/solvent can be misted before vaporization. As those skilled in the art, other precursors and tools and solvents can be used.

Suitable CVD deposition equipment is shown in U.S. Pat. No. 6,289,842; which is assigned to the assignee herein, and whose disclosure is hereby incorporated by reference.

### Example 4

Other processes may also be appropriate: Laser Ablation, Liquid Source Misted Deposition, Molecular Beam Deposition/Epitaxy, Chemical Beam Deposition, Jet Vapor Deposition and other processes.

Utilizing standard equipment compositionally engineered CeₓMn_{y}O₃ can be made using laser ablation from a single target of pre-mixed CeₓMn_{y}O₃ where the film composition is approximately that of the starting composition. The composition can be set to yield a dielectric or a ferroelectric. Alternatively two targets can be used—one for Ce (CeO) and one for Mn (MnO). In another alternative the targets are the elements (Ce and Mn) and a natural equilibrium oxide is allowed to form during the ablation process. In another two target process, two ablation targets are used and the rate ablation of one with respect to the other is changed over the course of the deposition by varying the duration, number or power (and to a lesser extent other process parameters such as pressure, gas composition, target bias, target and/or substrate temperature and the like) of the pulses.

Process Parameters and Enhancements

The above described deposition examples utilize substrate temperatures in the range from ˜350° C. to 1000° C. The deposition pressure for the CVD process range from milliTorr to atmosphere, similar for any misting steps, sol-gel processes generally take place at atmospheric pressure. Sputtering or Laser ablation processes generally take place at 10E⁻⁶ to ˜10E-²⁻² Torr pressures. Typically an oxidizing atmosphere is used: O₂, H₂O, N₂O, and similar oxidizers with an inert background.

The properties of the compositionally graded CeₓMn_{y}O₃ can be enhanced by the use of one or more of the following process steps:

1) Exposing the substrate to UV light to enhance mobility, chemistry and/or improve crystallinity.

2) Generating a plasma in a low pressure CVD process to either enhance the activity of all of the species in the reactor, or separated sectionally to preferentially enhance the activity of just the oxidizer.

3) Adding one or more additional sources of a nature similar to the process chemicals to dope the resulting CeₓMn_{y}O₃ film and thus modify the properties of the film

4) Heat treating the CeₓMn_{y}O₃ in the range from the deposition temperature to 1000 C. (or greater, but with diminishing effect) to modify the crystallinity and thus its ferroelectric or dielectric properties.

5) Heat treating the CeₓMn_{y}O₃ by subjecting it to laser pulses of varying energy and/or of various pulse length and or of various number of pulses to modify the crystallinity and thus ferroelectric or dielectric properties.

Representative Samples

A number of samples of were prepared by the CVD techniques described above and deposited on silicon and platinum wafers. The wafers were scribed into four quarters. One quarter was annealed at 800° C. for 30 minutes in oxygen environment. For all the wafers top electrode platinum was deposited by dc sputtering. The sputtered platinum was patterned with standard photolithographic techniques. The platinum was etched by ion milling. After removing the photoresist, the wafers were again annealed in oxygen atmosphere at 650° C. for 30 minutes to remove damage due to ion-milling. The C-V (capacitance versus voltage) characteristics were determined by HP 4275A LCR meter. HP-VEE software is used for automated measurement.

TABLE A

| Wafer | Composition | | | | Dielectric |
|---|---|---|---|---|---|
| No. | (starting) | Supplier | Thickness | Capacitance | Constant |
| 8 | Ce1.03Mn 0.97O on Pt | Toshima | 3750 A | 1.65 pF | 9.98 |
| 9 | Ce1.03Mn 0.97O on Si | Toshima | 2500 A | 2.02 pF | 8.15 |
| 10 | Ce1.09Mn0.91O on Pt | Toshima | 1200 A | 3.39 pF | 6.56 |
| 11 | Ce1.09Mn 0.91O on Si | Toshima | 1850 A | 3.78 pF | 11.2 |
| 12 | Ce0.75Mn 1.25O on Pt | Inorgtech | 700 A | 8.84 pF | 9.98 |
| 13 | Ce0.89Mn 1.11O on Pt | Inorgtech | 850 A | 8.20 pF | 11.25 |
| 14 | Ce0.25Mn 1.75O on Pt | Inorgtech | 900 A | 2.38 pF | 3.45 |
| 15 | Ce0.52Mn 1.48O on Pt | Inorgtech | 2200 A | 85.6 pF | 303.9 |
| 16 | Ce0.62Mn 1.38O on Pt | Inorgtech | 2050 A | 74.8 pF | 247.5 |
| 17 | Ce0.52Mn 1.48O on Si | Inorgtech | 800 A | 10.8 pF | 31.38* |
| 18 | Cerium oxide on Si | Inorgtech | 1150 A | 6.93 pF | 12.86 |

Table A shows the dielectric constant obtained by measured capacitance. The area of the capacitors is 70 microns by 100 microns, the measurement frequency is 100 kHz, with AC signal of 50 millivolts. For CeₓMn_{y}O₃ films on silicon, the capacitance corresponding to accumulation mode as well as maximum capacitance was used for the calculation.

Measurement of Samples

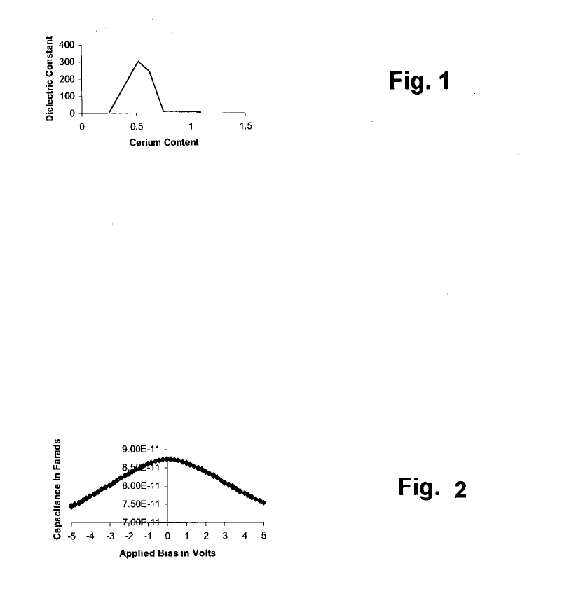

FIG. 1 shows the variation of dielectric constant with cerium content for the CeₓMn_{y}O₃ films of Table A on platinum. With increase in cerium content, initially the dielectric constant increases and a maximum dielectric constant of 303 was obtained for Ce 0.52 Mn1.48O. Further increase in cerium content resulted in decrease in the dielectric constant of the material. FIG. 2 shows the C-V curves for sample 16 (Ce0.62Mn 1.38O on Pt). The capacitance varies with voltage significantly which is commonly observed in ferroelectric materials like Barium strontium titanate (BST). But forward and reverse voltage sweeps did not show any shift in C-V characteristics.

The metal-ferroelectric-metal structure in Table A of sample 17 generally show more dielectric constant compared to films on silicon. For example, sample 9 shows less dielectric constant than sample 8 and this is due to the growth of silicon dioxide on silicon. In the case of sample 15 and 17 there is a significant difference in the dielectric constant. This is because sample 15 has higher dielectric constant on Platinum. Thin silicon dioxide grown on silicon during the deposition or annealing process has a lower series dielectric constant and therefore the overall dielectric constant will be significantly lower than that of sample 15. Thus, the material properties of CeₓMn_{y}O₃ can form both linear dielectric and non-linear ferroelectric on other substrate which it is deposited (metal or silicon). Other processing parameters would be expected to vary the resulting properties. The actual values reported in Table A are not meant to be actual but merely exemplary.

Semiconductor Devices

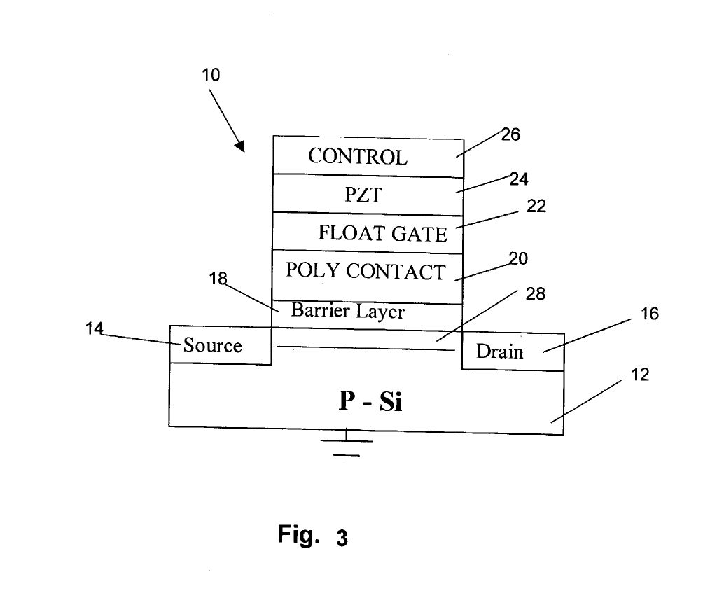

FIG. 3 shows a conventional Ferroelectric Field Effect Transistor (FeFET) 10 forming a single transistor (1T) non volatile Memory cell 10. Cell 10 is formed on a silicon substrate 12, which can be P or N type but is illustrated as P type herein. Substrate 12 includes a region 14 forming a source and a region 16 forming a drain which are created by standard IC implantation techniques. Disposed above substrate 12 is a necessary barrier layer 18 formed from silicon dioxide (SiO₂) or from Y₂O₃ and CeO₂, which are non-reactive with silicon, possess higher relative dielectric constants than silicon oxide (10-20 vs 4), and which are compatible with ferroelectric materials in a capacitor stack. However, Y₂O₃ and CeO₂ still require application of large switching voltages to overcome the dielectric mismatch with the ferroelectric material. Disposed above barrier layer 18 is a polysilicon contact layer 20 formed from polycrystalline silicon that is doped to create a conductive layer and deposited by standard Chemical Vapor Deposition (CVD) or sputter or other techniques. Disposed above polysilicon contact layer 20 is a floating gate 22 formed from Platinum deposited by Plasma Vapor Deposition (PVD). Usually, under the platinum floating gate 22 is an adhesion layer titanium metal or titanium oxide (Ti₂O₄) or Tantalum. A ferroelectric layer 24 disposed above floating gate 22 is formed from ferroelectric material such as PZT (lead zirconate titanate). Disposed above ferroelectric layer 24 is a control layer 26 formed from ferroelectric platinum or iridium oxide combined with iridium metal deposited by PVD.

In operation when the transistor 10 is “on” a conduction channel 28 is formed between source 14 and drain 16 allowing current flow therebetween. However, the dielectric mismatch and linear dielectric material such as Y₂O₃ and CeO₂ of barrier layer 18 in series with the silicon of substrate 12 leads to short memory retention through the creation of floating charges in the gate. Therefore, a different solution to these device issues is required for a successful nonvolatile DRAM from ferroelectric materials.

Memory retention and low voltage DRAM operation is obtainable by eliminating the separate barrier layer 18 in FIG. 2 and incorporating it directly in a ferroelectric CeₓMn_{y}O₃ film placed in the gate of a transistor. FIG. 3 shows the cross section of CeₓMn_{y}O₃ buffer/ferroelectric material in the gate of a transistor 30 forming a 1T memory cell constructed in accordance with the present invention. Transistor 30 comprises a silicon substrate 32, which again can be P or N type. Substrate 32 includes a region 34 forming a source and a region 36 forming a drain which are created by standard IC implantation techniques. Disposed above substrate 32 is a combined barrier layer/gate 38 formed from ferroelectric CeₓMn_{y}O₃. Disposed above barrier gate layer 38 is a polysilicon contact layer 40, again formed from polycrystalline silicon doped to create a conductive layer and deposited by CVD. In operation when the transistor 30 is “on” a conduction channel 42 is formed between source 34 and drain 36 allowing current flow therebetween

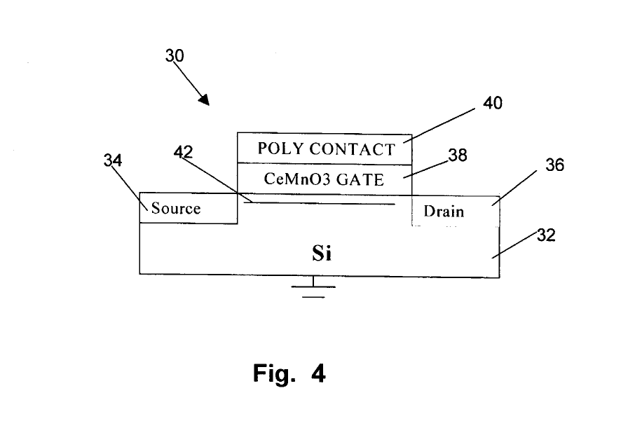

FIG. 4, in comparison to FIG. 3, illustrates the simplification of the gate structure by eliminating low dielectric serial capacitance in series with the silicon, which reduces the required applied gate voltage for inversion in substrate layer 32. Ferroelectric CeₓMn_{y}O₃ is a nonvolatile gate in a transistor in integrated circuit applications and can be produced with common integrated circuit fabrication methods.

The quantities of Ce and Mn can be adjusted in the deposition process such that the material is of ferroelectric phase or of dielectric phase. Generally speaking CeₓMn_{y}O₃ is optimally ferroelectric when Mn:Ce>2 depending on the processing conditions used However, sufficient ferroelectric properties exist to form a plurality of useful transistor devices even when the proportion of Mn to Ce is less than 2 The x and y values can be readily adjusted in the deposition process in accordance with the performance requirements of the finished device. Furthermore, the ferroelectric/dielectric properties of the as produced CeₓMn_{y}O₃ can readily be determined by measurement. In certain applications Pr, Nd, Sm, Eu, Gd, Tb, Dy, Ho, Er, Tm, V, Ca, Sr, Y, Cu and La can be substituted for or added with the Ce position and Hf, Zr, Ti, Mg, Al, Zn, Cd, Si, Ga, Ge, Sn, Mo, Nb and Ta can be substituted for or added with the Mn.

A low voltage memory window was accomplished by simplifying the stacked capacitor structure of a FeFET memory cell with placement of ferroelectric CeMnO₃ directly on the silicon surface as shown in FIG. 3. This is a fundamental breakthrough in the 1T device that eliminates the need for complicated stack integration that it replaces (shown in FIG. 3). The stacked FeFET structure needs to divide the supply voltage between the memory and linear gate (SiO₂) capacitors. In this configuration the majority of voltage is dropped across the linear dielectric layer leaving little voltage for ferroelectric switching. The solution to this issue is to produce a nonvolatile dielectric in the transistor gate that, unlike traditional ferroelectric layers PZT, SBT (Strontium Bismuth Tantalum Oxide), or BLT (Bismuth Lanthanum Titanium Oxide) can be directly formed on the silicon surface to produce a true NVDRAM structure. CeₓMn_{y}O₃ stability on Si with respect to temperature has been demonstrated by annealing through 950 C. and measuring gate dielectric performance. CeₓMn_{y}O₃ is stable with silicon and when used as a ferroelectric transistor gate material by adding a B site atom (Mn) forming a ferroelectric crystal, forms a 1T nonvolatile memory cell. The exact ferroelectric phase boundary (the composition where ferroelectric properties are present) is based on the process parameters and the substrate on which it is deposited.

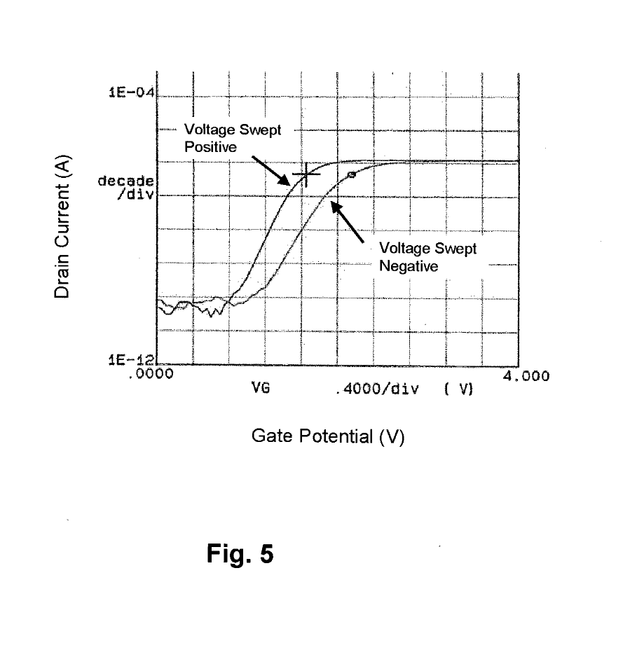

FIG. 5 shows data collected in support of this development. This figure shows the “memory window” of a ferrolectric field effect transistor (FeFET). The curve to the left in the figure shows the drain current (I_{d}) versus gate voltage (Vg) characteristics of the FeFET when the gate voltage is swept from 0 to 4V. The curve to the right shows the I_{d} versus Vg characteristics when the transistor is swept from 4 to 0V. Note that we have a very significant hysteresis in the Id versus Vg transfer characteristics i.e. the curves do not overlap. The retained polarization in the Fe gate is having a direct influence on the silicon surface potential of the device and thus altering the threshold voltage of the transistor by approximately 0.5V. The change in drain current between the two voltage sweeps at a fixed voltage (approximately 1.5V) is over 1 order of magnitude. Note that this device exhibits a significant hysteresis in the transfer characteristics and thus a sizeable potential memory window

Non-volatile Integrated Gate Bipolar Junction Transistor

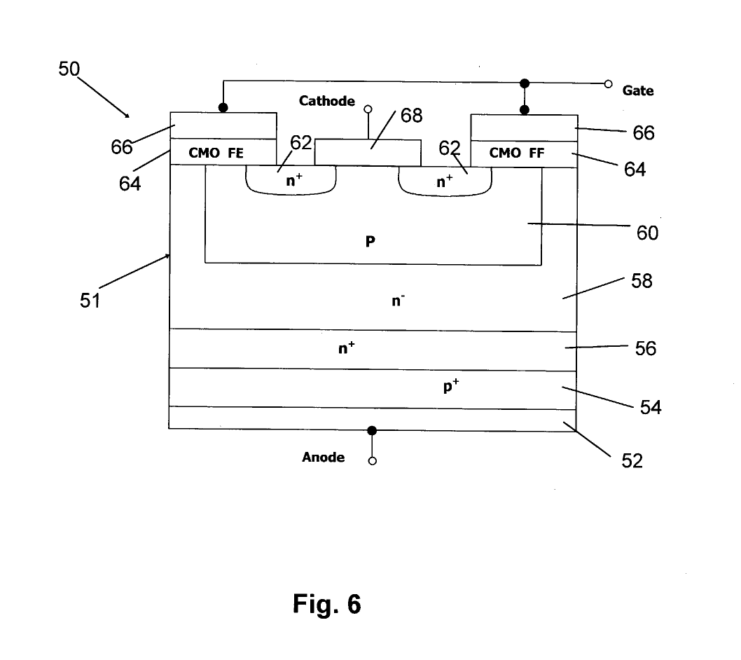

FIG. 6 shows an Non-volatile Integrated Gate Bipolar Transistor (NVIGBJT) 50 utilizing a ferroelectric layer disposed between the gate(s) and the substrate 51. The substrate includes a conductive layer 52 forming an anode (NVIGBJT collector) with a p+ layer 54, disposed above conductive layer 52, forming a bipolar emitter. A n+ buffer layer 56 is disposed between bipolar emitter layer 54 and an n− bipolar base/drift region 58. A p well 60 is disposed in region 58 forming a bipolar collector. Two n+ wells 62 are disposed in well 60 towards the upper part of substrate 51. Ferroelectric, CeₓMn_{y}O₃. layers 64 are deposited across the top of substrate 51 so as to contact wells 60,62 and base region 58. Contact layers 66 (which can be formed from any suitable conductive materials such as poly-Si) are deposited atop ferroelectric layers 64. A contact layer 68 disposed so as to contact wells 60 and 62 forms the cathode (NVIGBJT emitter).

The use of a ferroelectric layer to replace the SiO₂ buffer layer in an Integrated Gate Bipolar Transistor provides a non-volatile device which will continue to conduct after the biasing voltage is removed a property caused by the nonlinear action of the ferroelectric material as shown in FIG. 4 herein. This is in contrast to the standard IGBJT which will not conduct after the biasing voltage is removed. In order to turn the NVIGBJT “off” the device is reversed biased. The creation of a nonvolatile BJT device by the use of ferroelectric CeₓMn_{y}O₃ is a fundamental improvement to the technology as there are no existing nonvolatile BJT devices.

The disclosure herein pertaining to Si based devices is generally applicable to SiC or SiGe or diamond based devices and substrates. Additionally, an important aspect of CeₓMn_{y}O₃ described herein is that it is also compatible with compound semiconductors such as InP, GaAs, InSb, GaN, ZnO, SnO, ZnSe, CdTe, ZnTe and their alloys in that the CMO system can be used to form an oxide as a dielectric or a tandem dielectric—ferroelectric in a memory or other device. In certain applications a cerium oxide (CeOx) buffer layer or seed layer is used in series with the CeₓMn_{y}O₃ in order to mitigate any Mn diffusion into the substrate or dopants from the substrate into the CeₓMn_{y}O₃. The compatibility of CeₓMn_{y}O₃ for use in compound semiconductors is an important breakthrough as any Si device can be repeated in SiGe, SiC, and even diamond

Other device applications which may benefit from CeₓMn_{y}O₃ innovations described herein include opto-electronics, pyroelectrics and displays, among others. The invention has been described with respect to preferred embodiments. However, as those skilled in the art will recognize, modifications and variations in the specific details which have been described and illustrated herein may be resorted to without departing from the spirit and scope of the invention

What is claimed is:

1. An electronic device having a component comprising compositionally engineered CeₓMn_{y}O₃.

2. The electronic device as claimed in claim 1 wherein the CeₓMn_{y}O₃ is compositionally engineered so as to be ferroelectric.

3. The electronic device as claimed in claim 2, wherein the ferroelectric CeₓMn_{y}O₃ component forms the gate of a transistor.

4. The electronic device as claimed in claim 1 wherein the device includes multiple layers that are compositionally engineered.

5. The electronic device as claimed in claim 1, wherein the CeₓMn_{y}O₃ component is deposited on a substrate selected from the group of silicon, SiC, SiGe and diamond.

6. The electronic device as claimed in claim 5 wherein the CeₓMn_{y}O₃ is compositionally engineered so as to be ferroelectric and wherein the substrate includes a base-emitter region wherein the ferroelectric CeₓMn_{y}O₃ is disposed.

7. The electronic device as claimed in claim 5 wherein the CeₓMn_{y}O₃ is compositionally engineered so as to be ferroelectric and wherein the Si substrate includes a base-collector region wherein the ferroelectric CeₓMn_{y}O₃ is disposed.

8. The electronic device as claimed in claim 5 wherein the CeₓMn_{y}O₃ is compositionally engineered so as to be ferroelectric and wherein the Si substrate includes a base region where the ferroelectric CeₓMn_{y}O₃ modulates the gain of the base.

9. The electronic device as claimed in claim 1 wherein the device has a p region and an n region and wherein ferroelectric CeₓMn_{y}O₃ is disposed at the junction.

10. The electronic device as claimed in claim 1, wherein the CeₓMn_{y}O₃ component is deposited on a polycrystalline silicon layer

11. The electronic device as claimed in claim 1, wherein the CeₓMn_{y}O₃ component is deposited on a conducting layer in contact with a semiconducting layer.

12. The electronic device as claimed in claim 1, wherein the CeₓMn_{y}O₃ component is deposited on a conducting layer.

13. The electronic device as claimed in claim 1, wherein the CeₓMn_{y}O₃ component is deposited on a substrate by a process selected from the group of: chemical vapor deposition, sputtering, spin-on metal organic decomposition, molecular beam deposition/epitaxy, liquid source chemical deposition, chemical beam deposition/epitaxy and laser ablation.

14. The electronic device as claimed in claim 1 wherein the device is at least one of a n-p-n and a p-n-p device having a base-emitter collector wherein the CeₓMn_{y}O₃ is compositionally engineered so as to be ferroelectric and forms the base of the device.

15. The electronic device as claimed in claim 1 wherein the CeₓMn_{y}O₃ is compositionally controlled so as to be dielectric.

16. The electronic device as claimed in claim 15, wherein the dielectric CeₓMn_{y}O₃ component is a capacitor.

17. The electronic device as claimed in claim 1, wherein Mn:Ce>2.

18. The electronic device as claimed in claim 1 wherein the CeₓMn_{y}O₃ is compositionally graded so as to change from dielectric to ferroelectric.

19. The electronic device as claimed in claim 1 wherein the device includes a CeₓMn_{y}O₃ dielectric is in series with a ferroelectric CeₓMn_{y}O₃.

20. The electronic device as claimed in claim 1, wherein the device includes a CeOx layer.

21. A transistor comprising:
a substrate, having a source region and a drain region,
a gate disposed between the source and drain regions, said gate comprising ferroelectric CeₓMn_{y}O₃.

22. The transistor as claimed in claim 18, wherein Mn:Ce>2.

23. The transistor as claimed in claim 21, wherein the ferroelectric CeₓMn_{y}O₃ gate is deposited on the substrate by a process selected from the group of: chemical vapor deposition, sputtering, spin-on metal organic decomposition and laser ablation.

24. The transistor as claimed in claim 23, further including a contact layer disposed atop the ferroelectric CeₓMn_{y}O₃ gate.

25. The transistor as claimed in claim 21, wherein the contact layer comprises polysilicon.

26. The transistor as claimed in claim 21, wherein the substrate is selected from the group of silicon, SiC, SiGe and diamond.

27. A non volatile memory cell comprising a single transistor having a gate formed from ferroelectric CeₓMn_{y}O₃.

28. The non volatile memory cell as claimed in claim 27, wherein Mn:Ce>2

29. The non volatile memory cell as claimed in claim 27, wherein the transistor is formed on a substrate.

30. The non volatile memory cell as claimed in claim 29, wherein the substrate includes a source region and a drain region and wherein the ferroelectric CeₓMn_{y}O₃ gate is disposed between the source and drain regions.

31. The non volatile memory cell as claimed in claim 27, wherein the cell comprises an integrated gate bipolar junction transistor.
